(19) United States
(12) Patent Application Publication
(10) Pub. No.: US 2024/0248410 A1
(43) Pub. Date: Jul. 25, 2024

(54) EUV ILLUMINATION DEVICE AND METHOD FOR OPERATING A MICROLITHOGRAPHIC PROJECTION EXPOSURE APPARATUS DESIGNED FOR OPERATION IN THE EUV

(71) Applicant: Carl Zeiss SMT GmbH, Oberkochen (DE)

(72) Inventor: Michael Patra, Oberkochen (DE)

(21) Appl. No.: 18/605,591

(22) Filed: Mar. 14, 2024

Related U.S. Application Data
(63) Continuation of application No. PCT/EP2022/074741, filed on Sep. 6, 2022.

(30) Foreign Application Priority Data
Sep. 21, 2021 (DE) 10 2021 210 492.4

(51) Int. Cl. G03F 7/00; G02B 17/08

(52) U.S. Cl. CPC G03F 7/70316; G02B 17/0892; G03F 7/70033; G03F 7/70166; G03F 7/70191; G03F 7/702; G03F 7/70233; G03F 7/70308

(57) ABSTRACT

An EUV illumination device and related method for operating a microlithographic projection exposure apparatus designed for operation in the EUV. An EUV illumination device comprises a first reflective component, a second reflective component and an exchange apparatus by which the first reflective component and the second reflective component in the optical beam path are exchangeable for one another. A polarization degree, defined as a ratio between the reflectivities for s-polarized and p-polarized radiation, for the first reflective component is at least 1.5 times greater than for the second reflective component.

### CROSS-REFERENCE TO RELATED APPLICATIONS

The present application is a continuation of, and claims benefit under 35 USC 120 to, international application No. PCT/EP2022/074741, filed Sep. 6, 2022, which claims benefit under 35 USC 119 of German Application No. 10 2021 210 492.4, filed Sep. 21, 2021. The entire disclosure of each these applications is incorporated by reference herein.

### FIELD

The disclosure relates to an EUV illumination device and to a method for operating a microlithographic projection exposure apparatus designed for operation in the EUV.

### BACKGROUND

Microlithography is used for producing microstructured components, such as for example integrated circuits or LCDs. The microlithography process is conducted in what is called a projection exposure apparatus, which comprises an illumination device and a projection lens. The image of a mask (=reticle) illuminated via the illumination device is projected here via the projection lens onto a substrate (e.g. a silicon wafer) that is coated with a light-sensitive layer (photoresist) and arranged in the image plane of the projection lens, in order to transfer the mask structure onto the light-sensitive coating of the substrate.

In projection lenses designed for the EUV range, i.e. at wavelengths of, e.g., approximately 13 nm or approximately 7 nm, mirrors are used as optical components for the imaging process owing to the general lack of availability of suitable light-transmissive refractive materials.

During the operation of a projection exposure apparatus it is typically desirable to set specific polarization distributions in the pupil plane and/or in the reticle in a targeted manner in the illumination device for the purpose of optimizing the imaging contrast and also to be able to carry out a change in the polarization distribution during the operation of the projection exposure apparatus. Thus, the use of s-polarized radiation may be advantageous for the purposes of obtaining the highest possible image contrast especially in the case of a projection exposure apparatus for imaging specific structures when the so-called vector effect in the case of relatively large values of the numerical aperture (NA) is taken into account.

However, scenarios where the use of unpolarized radiation rather than an operation with polarized radiation is advantageous also occur in practice during the operation of a projection exposure apparatus. By way of example, this may be the case even for high values of the numerical aperture (NA) if the structures to be imaged within the scope of the lithography process are not linear structures or structures that otherwise define a preferred orientation but structures without a preferred orientation (e.g. contact holes). In the latter case, the use of linearly polarized radiation might not only fail to yield an advantage but might be found to be disadvantageous as a consequence of an induced unwanted asymmetry.

Further relevant circumstances are given by the fact that the initial production of unpolarized radiation by the utilized EUV source (e.g. a plasma source), as is conventional, is typically accompanied by a loss of radiant flux—specifically as a consequence of the desired output coupling of the respective unwanted polarization component—when polarized radiation is provided, which in turn impairs the performance of the projection exposure apparatus.

Consequently, if the aforementioned aspects are taken into account, it can be desirable in practice to be able to switch between an operating mode with polarized radiation and an operating mode with unpolarized radiation, depending on the operating scenario of the projection exposure apparatus—and for example depending on the structures to be imaged in each case.

However, the implementation of such a switchover might made more difficult in a projection exposure apparatus designed for operation in EUV because, firstly, it is generally desirable for the beam geometry applicable with respect to the beam entry into the illumination device or the beam exit from the illumination device to be maintained from practical points of view but, secondly, in general no suitable transmissive polarization-optical components such as beam splitters are available in the relevant EUV wavelength range. However, the polarization manipulation on the basis of a reflection below the Brewster angle, as is available in the EUV range, is usually accompanied by the introduction of one or more additional beam deflections and hence can involve a significant light loss if an unchanging beam geometry is ensured at the same time.

Reference is made, purely by way of example, to DE 10 2008 002 749 A1, DE 10 2018 207 410 A1 and publication M. Y. Tan et al.: “Design of transmission multilayer polarizer for soft X-ray using a merit function”, OPTICS EXPRESS Vol. 17, No. 4 (2009), pp. 2586-2599.

### SUMMARY

The present disclosure seeks to provide an EUV illumination device of a microlithographic projection exposure apparatus designed for operation in the EUV and a method for operating a microlithographic projection exposure apparatus designed for operation in the EUV, which can help facilitate a flexible switchover without transmission losses between an operation with polarized radiation and an operation with unpolarized radiation.

According to an aspect, the disclosure provides an EUV illumination device of a microlithographic projection exposure apparatus designed for operation in the EUV including:
a first reflective component;
a second reflective component; and
an exchange apparatus by which the first reflective component and the second reflective component in the optical beam path are exchangeable for one another;
wherein a polarization degree, defined as a ratio between the reflectivities for s-polarized and p-polarized radiation, is greater for the first reflective component by a factor of at least 1.5 than for the second reflective component.

Within the meaning of the present application, an illumination device is understood to mean an optical system which illuminates a reticle with a defined spatial and angular distribution by virtue of the radiation of a real or virtual light source being suitably reshaped. In embodiments, for example, the EUV illumination device according to the disclosure can receive the radiation of a plasma (i.e. a real light source) via a collector. In further embodiments, the EUV illumination device can also receive the radiation from an intermediate focus (i.e. a virtual light source).

For example, the disclosure involves realizing a flexible switchover between a polarized operating mode and an unpolarized operating mode in an EUV illumination device, depending on the application scenario and depending on the structures to be imaged in the lithography process in each case, which switchover avoids additional beam deflections, by virtue of exchanging a reflective component situated in the optical beam path of the illumination device for another reflective component with an identical surface geometry but with a different reflection layer system.

According to the disclosure, the provision of two different reflective components which are exchangeable for one another and, as explained below, differ in terms of their spectral reflection profiles for s-polarized and p-polarized radiation but otherwise correspond to one another with respect to their surface geometry can have the consequence that the overall geometry of the beam path within the illumination device remains unchanged even after an exchange of one component for the other component taking place for the purpose of a switchover between polarized and unpolarized operation (i.e. a change between a polarizing and an unpolarizing illumination device) and hence that no additional beam deflections, which are accompanied by an unwanted light loss, are present.

In this case, the disclosure can involve the insight obtained by the inventor on the basis of comprehensive simulation investigations that the spectral reflection profiles which are respectively applicable to s-polarized and p-polarized radiation and which are provided by the respective reflection layer systems of the reflective components that have been exchanged for one another according to the disclosure can be shifted in a targeted manner by way of a suitable adaptation (e.g. thickness scaling of the individual layers forming the layer stack of the reflection layer system) relative to the relevant “transmission interval” of the entire optical system (i.e. in particular, the downstream optical components of the illumination device in the beam path).

This targeted adaptation or shift of the spectral reflection profiles applicable to the s-polarized and p-polarized radiation can in turn be implemented, for example, so that, for the reflective component used in the “polarized operation” of the illumination device or projection exposure apparatus, the spectral reflection profile applicable to s-polarized radiation but not the spectral reflection profile with the respective maximum reflectivity values applicable to p-polarized radiation is located within the transmission range of the optical system. By contrast, the targeted adaptation or shift of the spectral reflection profiles applicable to the s-polarized and p-polarized radiation can be implemented for the reflective component used in the “unpolarized operation” of the illumination device or projection exposure apparatus in such a way that the maximum reflectivity values of both spectral reflection profiles (i.e. both the spectral reflection profile for p-polarized radiation and the spectral reflection profile for s-polarized radiation) are located within the transmission range.

According to an embodiment, a wavelength λ₀ exists as mean wavelength in a specified wavelength interval [(λ₀−Δλ₀/2), (λ₀+Δλ₀/2)] of width Δλ₀ such that the first reflection layer system satisfies the following conditions:

$$( {λ}_{0} - Δ {λ}_{0} / 2 ) \geq {λ}_{1 s l} , ( {λ}_{0} + Δ {λ}_{0} / 2 ) \leq {λ}_{1 s r}$$

$$and$$

$$( {λ}_{0} - Δ {λ}_{0} / 2 ) \leq {λ}_{1 pl} or ( {λ}_{0} + Δ {λ}_{0} / 2 ) \geq {λ}_{1 pr} ,$$

where, in the reflection profiles (r₁ₛ(λ), r₁ₚ(λ)) of the first reflection layer system, λ₁ₛₗ and λ₁ₚₗ denote the shortest wavelength and λ₁ₛᵣ and λ₁ₚᵣ denote the longest wavelength for which in each case s-polarized and p-polarized radiation, respectively, is reflected with a reflectivity of at least 50% of the maximum reflectivity.

According to an embodiment, a wavelength λ₀ exists as mean wavelength in a specified wavelength interval [(λ₀−Δλ₀/2), (20+Δλ₀/2)] of width Δλ₀ such that the second reflection layer system satisfies the following conditions:

$$( {λ}_{0} - Δ {λ}_{0} / 2 ) \geq {λ}_{2 s l} , ( {λ}_{0} + Δ {λ}_{0} / 2 ) \leq {λ}_{2 s r}$$

$$and$$

$$( {λ}_{0} - Δ {λ}_{0} / 2 ) \geq {λ}_{2 p l} , ( {λ}_{0} + Δ {λ}_{0} / 2 ) \leq {λ}_{2 p r}$$

where, in the reflection profiles (r₂ₛ(λ), r₂ₚ(λ)) of the second reflection layer system, λ₂ₛₗ and λ₂ₚₗ denote the shortest wavelength and λ₂ₛᵣ and λ₂ₚᵣ denote the longest wavelength for which in each case s-polarized and p-polarized radiation, respectively, is reflected with a reflectivity of at least 50% of the maximum reflectivity.

Analogously to the aforementioned considerations, it is also possible for the EUV illumination device for a wavelength interval [( [symbol] − [symbol] );( [symbol] + [symbol] )] to be defined in which the transmissivity is at least 50% of the maximum transmissivity of the EUV illumination device. According to one embodiment, Δλ₀ lies between [symbol] and

[symbol]

The stated transmission range [(λ₀−Δλ₀/2), (λ₀+Δλ₀/2)] of the projection exposure apparatus differs from the transmission range [( [symbol] − [symbol] );( [symbol] + [symbol] )] of the pure illumination device because a transmission range becomes narrower the more reflections take place at mirrors. The width of the transmission range falls approximately with the square root of the number of reflections. In a typical scenario, a fraction of between ½ and ¼ of the total number of reflections takes place in the illumination device, with the result that the width of the stated transmission range lies between 1/\sqrt{2} and ½ of the width of the transmission range of the illumination device.

In embodiments of the disclosure, both the first and the second reflective component can be a facet mirror, such as a pupil facet mirror having a plurality of pupil facets or a field facet mirror having a plurality of field facets. In further embodiments, both the first and the second reflective components can also comprise at least one mirror facet of a facet mirror each, such as a pupil facet mirror or a field facet mirror.

In further embodiments, the first and the second reflective component can also each comprise at least one micromirror of a specular reflector.

In further embodiments, the first and the second reflective component can each be a collector mirror.

The disclosure furthermore also relates to a method of operating a microlithographic projection exposure apparatus designed for operation in the EUV, wherein an object plane of a projection lens is illuminated using an illumination device and wherein the object plane is imaged with the projection lens into an image plane of the projection lens, wherein a first reflective component with a first reflection layer system located in the optical beam path of the illumination device is exchanged for a second reflective component with a second reflection layer system for switching between a polarized operating mode and an unpolarized operating mode, and wherein a polarization degree, defined as a ratio between the reflectivities for s-polarized and p-polarized radiation, is greater for the first reflective component by a factor of at least 1.5 than for the second reflective component.

Further configurations of the disclosure are evident from the description and the dependent claims.

The disclosure is explained in greater detail below on the basis of exemplary embodiments illustrated in the accompanying figures.

### BRIEF DESCRIPTION OF THE DRAWINGS

In the figures:

FIGS. 1A-1D show diagrams for elucidating different values of the reflectivity for s-polarization and p-polarization, which are obtainable by varying the layer parameters of a reflection layer system;

FIG. 2 shows a typical wavelength-dependent profile of the intensity corresponding to an exemplary transmission interval of an optical system;

FIGS. 3A-3B show the wavelength-dependent profile of the reflectivity of two different reflection layer systems in each case for s-polarization and p-polarization;

FIGS. 4A-4B show the respective wavelength-dependent profile of the reflectivity of two different reflection layer systems over a larger wavelength range;

FIG. 5 shows a diagram for explaining terminology used within the present application;

FIGS. 6A-6F show diagrams which show layer thicknesses of periodic layer systems for exemplary angles of incidence, wherein, for the entire range of rₛ, the layers with minimum and maximum rₚ are represented in each case;

FIGS. 7A-7H show diagrams in which regions in the rₛ-rₚ diagram obtainable for exemplary periodic or aperiodic layer stacks are represented as a function of the angle of incidence;

FIG. 8 shows a schematic and much simplified representation of the possible structure of an illumination device;

FIG. 9 shows a schematic illustration for elucidating an exemplary realization of the disclosure in a pupil facet mirror;

FIG. 10 shows a schematic illustration for elucidating a further possible realization of the disclosure in segments of a pupil facet mirror;

FIG. 11 shows a schematic illustration for elucidating a further possible realization in individual pupil facets of a pupil facet mirror;

FIGS. 12A-12B show schematic illustrations for explaining a further possible realization of the disclosure in a field facet mirror; and

FIG. 13 shows a schematic illustration of a fundamentally possible structure of a projection exposure apparatus designed for operation in the EUV.

### DETAILED DESCRIPTION

What is common to the embodiments of the disclosure described below is the basic concept of providing two reflective optical components with differing spectral reflection profiles in a manner such that, for a specified wavelength interval, one of the two components is suitable for a polarized operating mode and the other of the two components is suitable for an unpolarized operating mode. In this case, the aforementioned wavelength interval can be in particular a transmission interval of the respective optical system (e.g. the illumination device of a microlithographic projection exposure apparatus) for which the reflective optical components according to the disclosure are intended and which is typically determined by the reflection profile of the remaining optical components present in the optical system (in particular, the downstream optical components in relation to the optical beam path).

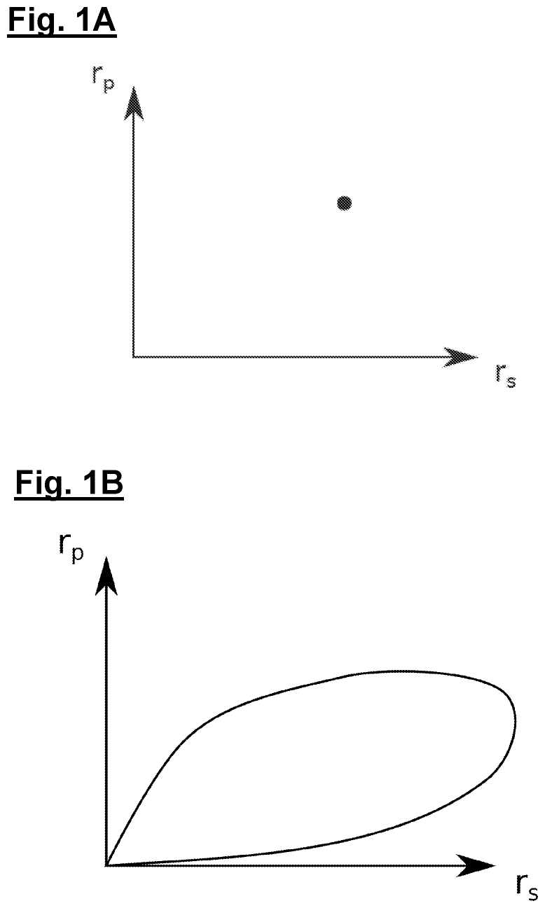

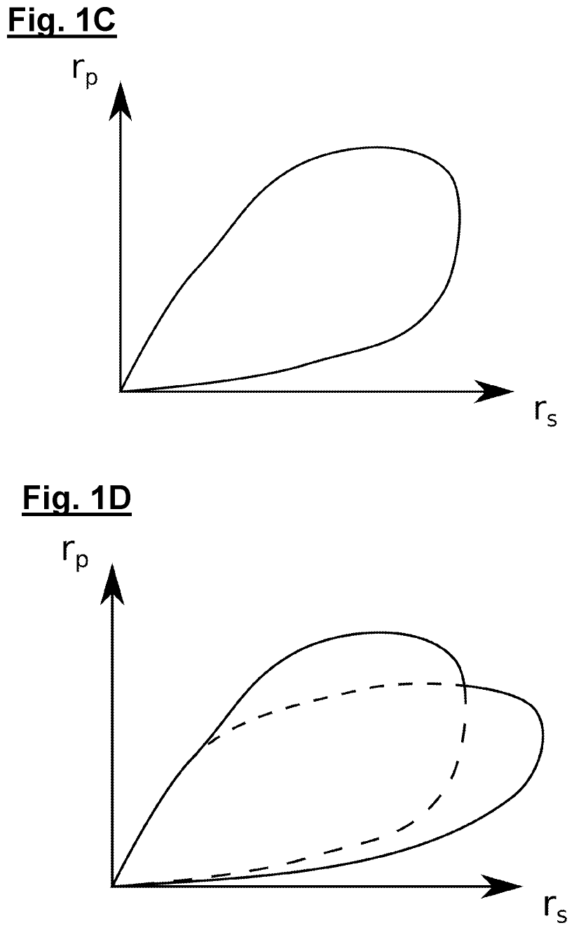

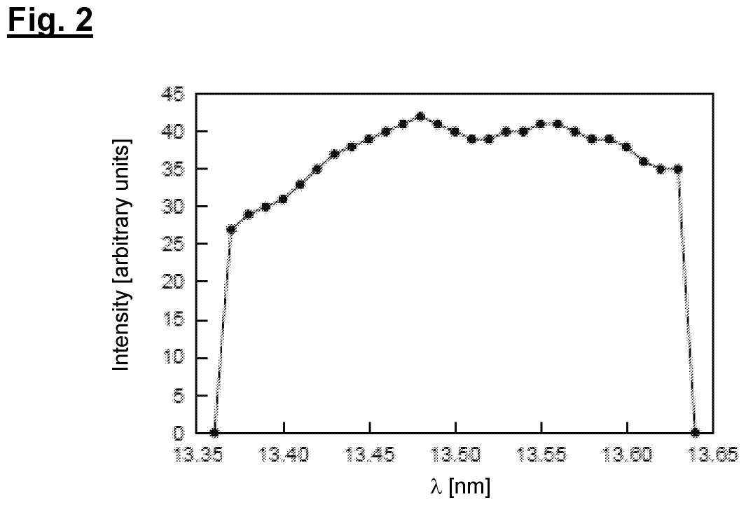

Below, the principle underlying the aforementioned targeted adjustment of the respective reflection layer systems of the reflective optical components according to the disclosure for the polarized and unpolarized operation, respectively, is initially explained with reference to the diagrams in FIGS. 1-5.

In general, a given reflection layer system for a specified angle of incidence and a specified wavelength spectrum of the electromagnetic radiation comprises a specific value Is for the reflectivity of s-polarized radiation and a specific value rₚ for the reflectivity of p-polarized radiation. Consequently, according to FIG. 1A, the reflection layer system can be represented as a single point in the rₛ-rₚ diagram.

For given materials of the individual layers within the reflection layer system, the values for rₛ and rₚ are, in turn, dependent on the respective layer thicknesses, and so reflection layer systems with different value pairs (rₛ, rₚ) can be provided by varying these layer thicknesses. As a result, the provision of a multiplicity of corresponding reflection layer systems with different value pairs (rₛ, rₚ) in each case allows coverage of a specific region in the rₛ-rₚ diagram, for example in accordance with FIG. 1B. The specific design of this “obtainable region” in the rₛ-rₚ diagram can in turn be varied by varying the material combinations of the individual layers within the reflection layer system, for the purposes of which FIG. 1C shows an exemplary further possible shape of an obtainable region in the rₛ-rₚ diagram.

Accordingly, a corresponding union of the relevant obtainable regions arises according to FIG. 1D if, over the multiplicity of provided reflection layer systems, corresponding different material combinations of the individual layers are admitted or are present in this multiplicity.

Hence, in general, the suitable selection of a defined point in the rₛ-rₚ diagram, which in turn corresponds to a uniquely defined layer structure, can be made depending on the intended use or operating mode and the correspondingly produced reflective optical component can be exchanged where desired following the simulation of a multiplicity of reflection layer systems or reflective optical components formed thereby. Once again, depending on the use scenario, this selection can alternatively be made either to maximize the total reflectance provided by the reflection layer system or to provide a specific degree of polarization (corresponding to a ratio of the reflectivities respectively obtained for s-polarized radiation and p-polarized radiation).

What can be observed in this context is that the ultimately practice-oriented or preferred value pairs (rₛ, rₚ) are located on the respective edge of the obtainable regions, for example according to FIGS. 1B-1D. These circumstances can be traced back to the fact that a point in the rₛ-rₚ diagram situated within the region enclosed by the edge is therefore generally not preferred because it is possible in each case to readily find a point located directly on the edge of the region or a corresponding value pair (rₛ, rₚ) which either has a higher reflectivity overall for the same degree of polarization or which yields a higher degree of polarization for the same reflectivity.

The reflection layer systems used according to the disclosure can be both periodic and aperiodic layer systems. To provide different spectral reflection profiles both for s-polarized and for p-polarized radiation, the corresponding layer designs are now suitably varied, with the consequence that the wavelength-dependent profile of the respective reflectivities Is and rₚ in the relevant transmission interval ultimately has the respective suitable shape for the polarized or unpolarized operation.

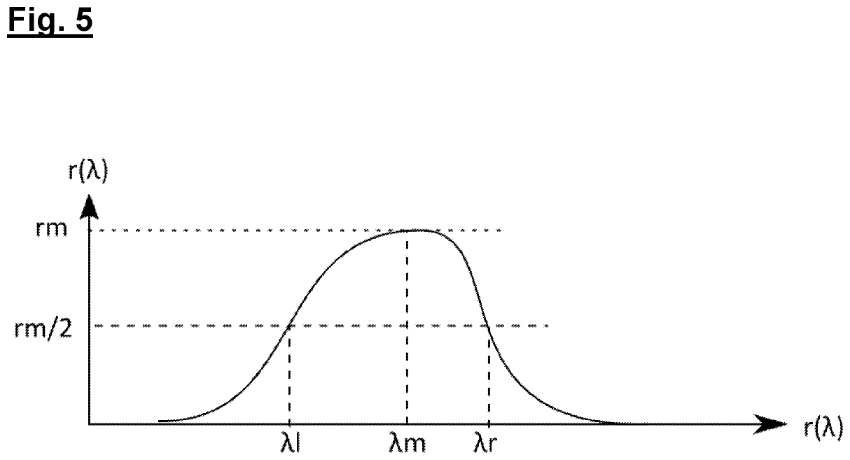

FIG. 2 initially shows the typical shape of the spectral radiant flux of an EUV radiation source. The curve has been cut off outside of the wavelength range which in fact also reaches the image plane or wafer plane in the optical system or in the illumination device when the respective spectral reflection profiles of the remaining optical components are taken into account. Since the spectral transmission profile of the optical system or the illumination device typically only approaches zero asymptotically, the two cut-off wavelengths can only be specified approximately in each case. FIG. 5 shows a diagram of a spectral reflection profile r(λ). Here, the maximum reflectivity rₘ occurs at the wavelength λₘ. The shortest wavelength for which radiation is reflected with a reflectivity of at least 50% of the maximum reflectivity is denoted by λ₁. The longest wavelength for which radiation is reflected with a reflectivity of at least 50% of the maximum reflectivity (corresponding to a reflectivity of rₘ/2) is denoted by λ_{f}.

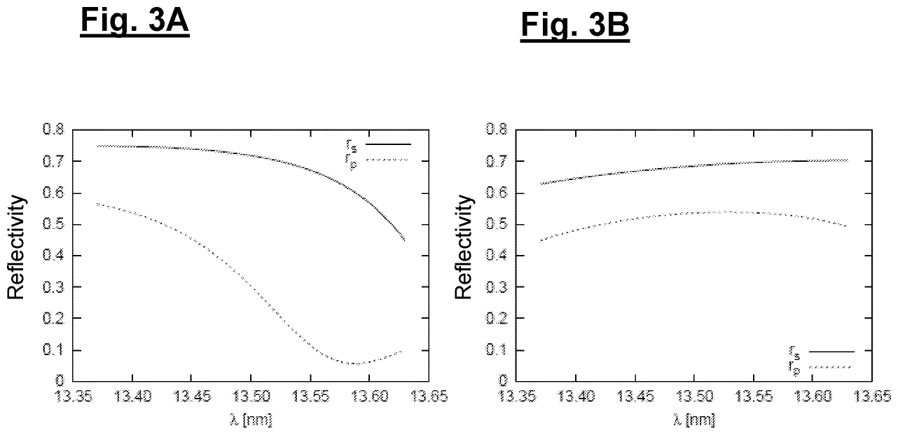

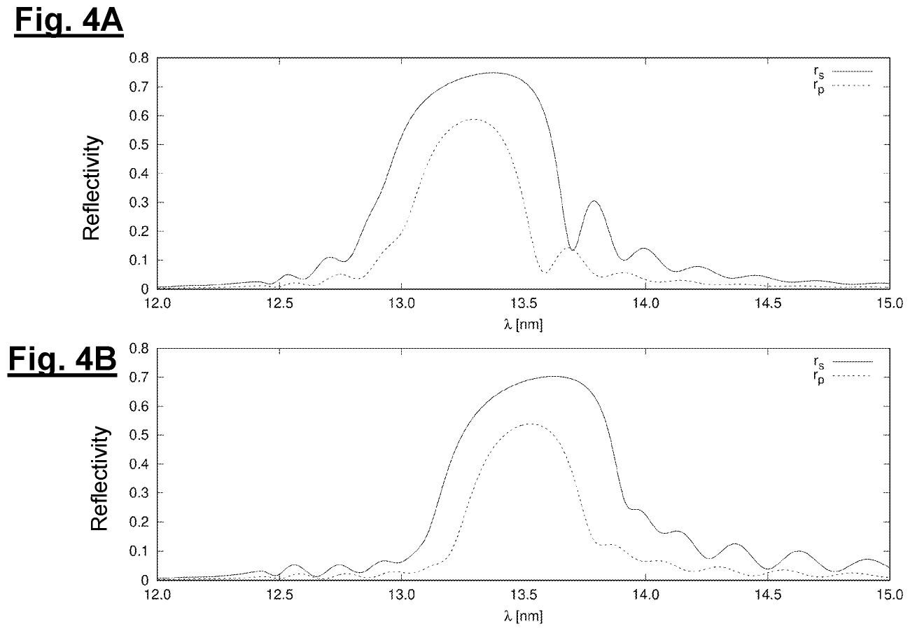

FIGS. 3A-3B show the respective wavelength-dependent curve of the reflectivity for s-polarization and p-polarization for two exemplary reflection layer systems (aperiodic Mo—Si layer systems in this example). In this case, the relevant multiple layer designs are chosen from a multiplicity of simulated layer designs such that the reflectivity rₚ obtained for p-polarized radiation is minimal for the reflection layer system according to FIG. 3A and maximal for the reflection layer system according to FIG. 3B. The qualitatively different curve of the wavelength-dependent reflectivity, readily identifiable from a comparison of FIG. 3A with FIG. 3B, becomes evident in terms of its practical relevance according to FIGS. 4A-4B during the respective consideration over a relatively large wavelength range.

As is evident from FIGS. 4A-4B, the peaks of the reflectivity respectively obtained for s-polarization and for p-polarization have different widths, with, according to expectations, the peak in the wavelength-dependent profile of the reflectivity having the greater width for s-polarization comparison with the peak for p-polarization. What is now achieved with the two aforementioned “extreme” layer designs with respect to the reflectivity rₚ applicable to p-polarization by taking advantage of this circumstance is that both peaks (i.e. for s-polarization and for p-polarization) are located within the transmission interval for the reflection layer system according to FIG. 4B, whereas the maximum reflectivity values for s-polarization but not for p-polarization are located within the transmission interval for the reflection layer system according to FIG. 4A (instead, for p-polarization, the falling slope of the corresponding peak of the reflectivity curve is situated within the transmission interval according to FIG. 4A).

As a consequence, the reflection layer system according to FIG. 4A has in comparison with that according to FIG. 4B a substantially stronger polarizing effect on the incident electromagnetic radiation. Expressed differently, the reflection layer system according to FIG. 4A is suitable for the operating mode with polarized radiation and the reflection layer system according to FIG. 4B is suitable for the operating mode with unpolarized radiation.

The realization of the above-described concept according to the disclosure in reflection layer systems in the form of aperiodic multiple layer systems now allows the influencing of the two parameters of width and position of the respective peak in the wavelength-dependent reflectivity profile independently of one another by changing the layer design. The corresponding values for s-polarization and p-polarization are correlated for a given layer design, and so width and position of the peaks for s-polarization and p-polarization cannot be chosen completely independently of one another. However, as already explained on the basis of FIGS. 4A-4B, this is not necessary either. By contrast, when realizing the disclosure with reflection layer systems in the form of periodic layer systems with an alternating periodic sequence of a given number of two different layer materials (“bilayer”), it is substantially only the position of the peak that can be chosen freely, while the width of the peak can only be influenced to a limited extent.

Tables 1-4 represent aperiodic layer designs in exemplary fashion, to be precise for systems made of molybdenum silicon (MoSi) or ruthenium silicon (RuSi). For fixed rₛ=0.7, the tables in each case specify the layer designs that have a maximum and minimum rₚ, respectively.

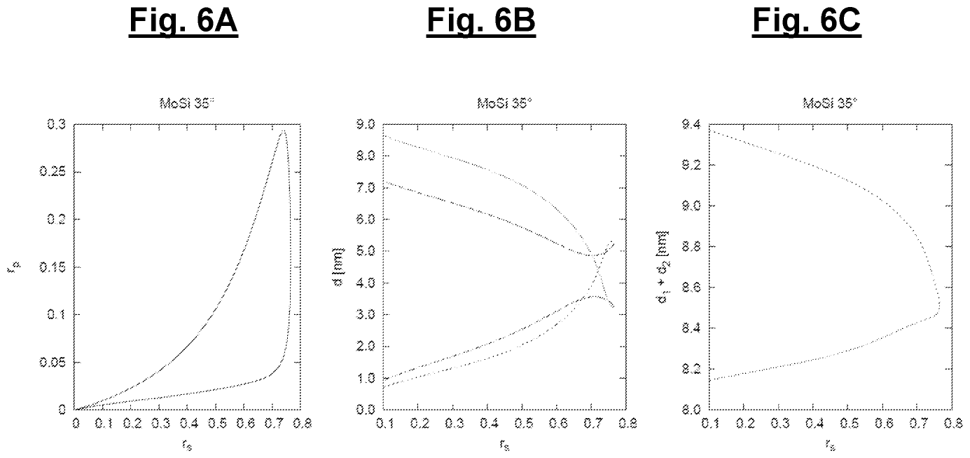

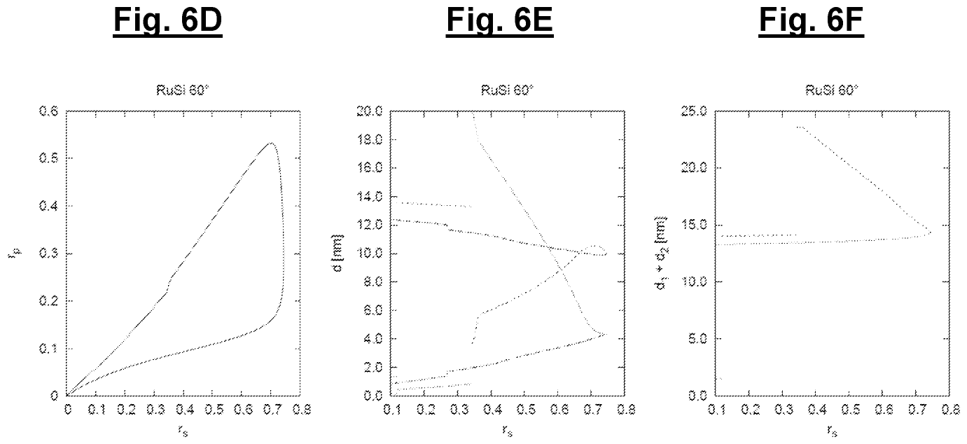

For exemplary angles of incidence, FIGS. 6A-6H depict the layer thicknesses of periodic layer systems. In this case, the layers with minimum and maximum rₚ are respectively depicted for the entire range of rₛ. FIGS. 6A and 6D each show the extremally achievable values of rₚ. FIGS. 6B and 6E each show the individual layer thicknesses: The thickness of silicon for maximum rₚ is represented by long dashes. The thickness of molybdenum or ruthenium for maximum rₚ is represented by short dashes.

The thickness of silicon for minimum rₚ is represented by a dash-dotted line. The thickness of molybdenum or ruthenium for minimum rₚ is represented by a line with a dash followed by two dots. FIGS. 6C and 6F show the respective period thickness, that is to say the sum of the two individual thicknesses (molybdenum and silicon or ruthenium and silicon).

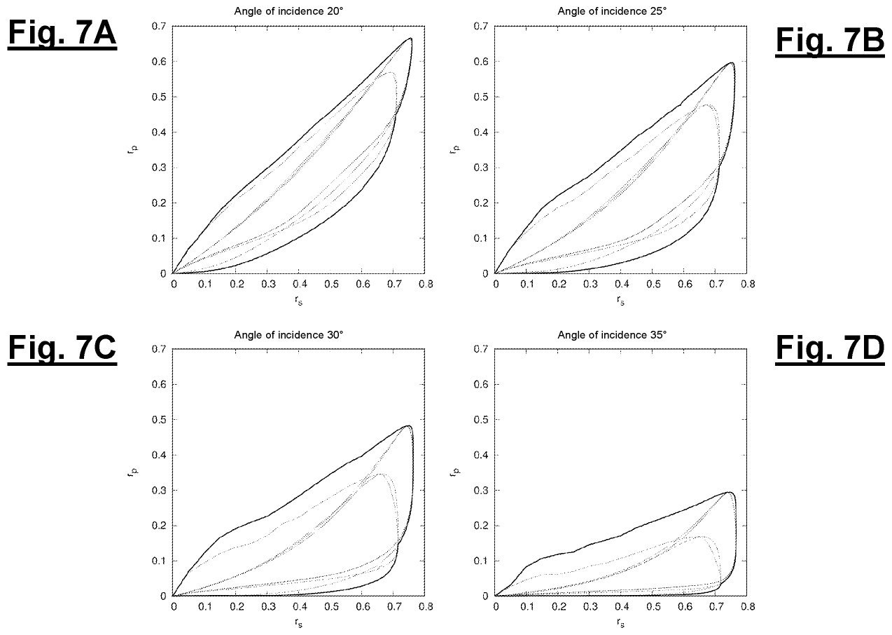

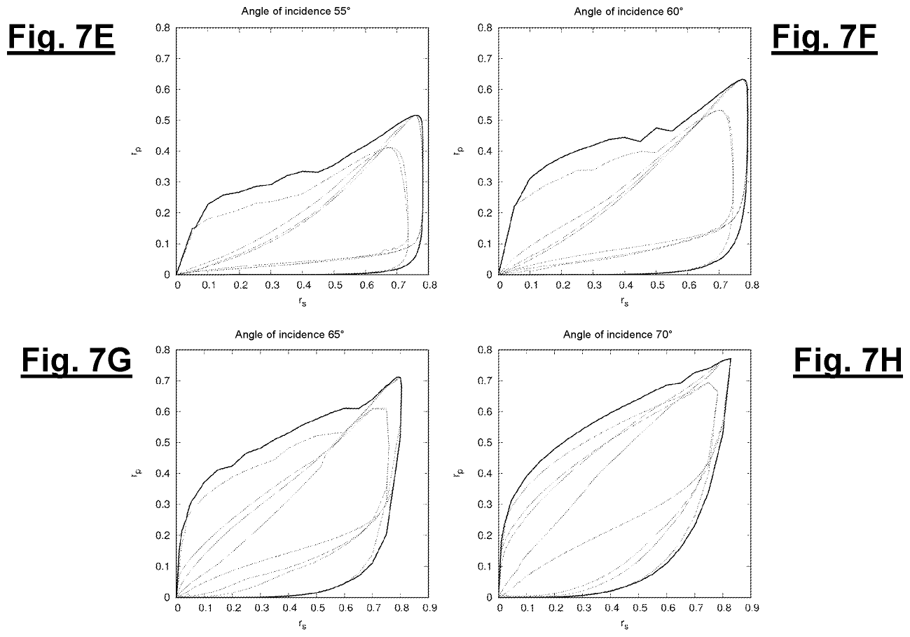

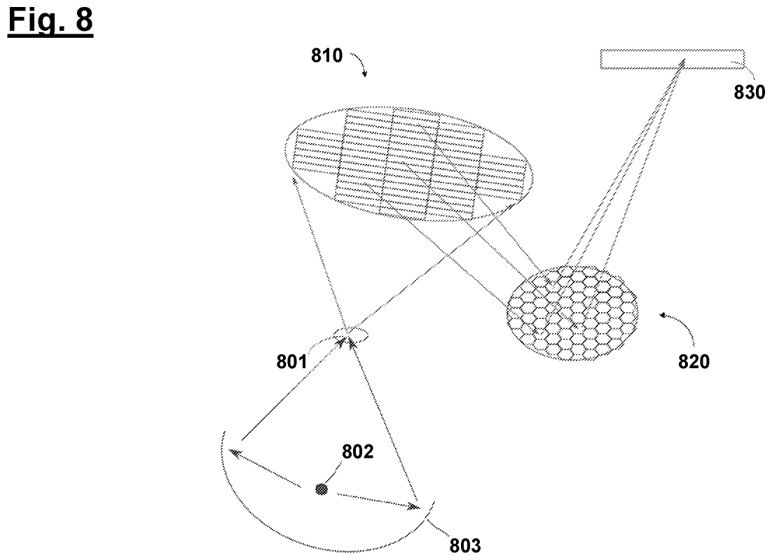

FIGS. 7A-7H show the range in the rₛ-rₚ diagram achievable for MoSi or RuSi by periodic or aperiodic layer stacks, as a function of the angle of incidence. The two components that can be exchanged for one another need not correspond with respect to the material combination (MoSi or RuSi) and/or with respect to the structure (periodic or aperiodic sequence). Especially for angles that are sufficiently different from 0° and the Brewster angle of approximately 45°, the available selection range in the rₛ-rₚ diagram is surprisingly large.

TABLE 1
(RuSi; 60° angle of incidence; rₛ = 0.7; rₚ minimal
The silicon layer of layer 1 is located directly on the
substrate. The ruthenium layer of layer 50 forms the
incidence surface for the EUV used radiation.)

| | | |
|---|---|---|
| 1 | d_{Si} = 14.0000 nm | d_{Ru} = 2.3451 nm |
| 2 | d_{Si} = 11.6620 nm | d_{Ru} = 0.0000 nm |
| 3 | d_{Si} = 0.0000 nm | d_{Ru} = 14.0000 nm |
| 4 | d_{Si} = 13.9930 nm | d_{Ru} = 14.0000 nm |
| 5 | d_{Si} = 0.0000 nm | d_{Ru} = 14.0000 nm |
| 6 | d_{Si} = 14.0000 nm | d_{Ru} = 0.0000 nm |
| 7 | d_{Si} = 14.0000 nm | d_{Ru} = 14.0000 nm |
| 8 | d_{Si} = 0.0000 nm | d_{Ru} = 14.0000 nm |
| 9 | d_{Si} = 0.0000 nm | d_{Ru} = 14.0000 nm |
| 10 | d_{Si} = 0.0000 nm | d_{Ru} = 0.0000 nm |
| 11 | d_{Si} = 14.0000 nm | d_{Ru} = 14.0000 nm |
| 12 | d_{Si} = 14.0000 nm | d_{Ru} = 14.0000 nm |
| 13 | d_{Si} = 0.0000 nm | d_{Ru} = 14.0000 nm |
| 14 | d_{Si} = 14.0000 nm | d_{Ru} = 0.0000 nm |
| 15 | d_{Si} = 0.0000 nm | d_{Ru} = 7.1140 nm |
| 16 | d_{Si} = 14.0000 nm | d_{Ru} = 14.0000 nm |
| 17 | d_{Si} = 14.0000 nm | d_{Ru} = 0.0000 nm |
| 18 | d_{Si} = 0.0000 nm | d_{Ru} = 6.0973 nm |
| 19 | d_{Si} = 8.5758 nm | d_{Ru} = 13.5046 nm |
| 20 | d_{Si} = 0.4454 nm | d_{Ru} = 11.4563 nm |
| 21 | d_{Si} = 7.0244 nm | d_{Ru} = 12.3895 nm |
| 22 | d_{Si} = 13.9996 nm | d_{Ru} = 10.4081 nm |
| 23 | d_{Si} = 3.4224 nm | d_{Ru} = 12.4434 nm |
| 24 | d_{Si} = 13.9985 nm | d_{Ru} = 13.9998 nm |
| 25 | d_{Si} = 14.0000 nm | d_{Ru} = 13.9996 nm |
| 26 | d_{Si} = 4.9534 nm | d_{Ru} = 13.9966 nm |
| 27 | d_{Si} = 0.0000 nm | d_{Ru} = 13.9966 nm |
| 28 | d_{Si} = 3.8489 nm | d_{Ru} = 12.8972 nm |
| 29 | d_{Si} = 0.0000 nm | d_{Ru} = 13.9958 nm |
| 30 | d_{Si} = 14.0000 nm | d_{Ru} = 14.0000 nm |
| 31 | d_{Si} = 14.0000 nm | d_{Ru} = 0.0000 nm |
| 32 | d_{Si} = 9.6313 nm | d_{Ru} = 1.7682 nm |
| 33 | d_{Si} = 11.4665 nm | d_{Ru} = 5.4774 nm |
| 34 | d_{Si} = 10.1439 nm | d_{Ru} = 6.3766 nm |
| 35 | d_{Si} = 9.7245 nm | d_{Ru} = 6.6627 nm |
| 36 | d_{Si} = 9.6146 nm | d_{Ru} = 6.6180 nm |
| 37 | d_{Si} = 9.6285 nm | d_{Ru} = 6.4776 nm |
| 38 | d_{Si} = 9.6654 nm | d_{Ru} = 6.2996 nm |
| 39 | d_{Si} = 9.6951 nm | d_{Ru} = 6.1137 nm |
| 40 | d_{Si} = 9.7058 nm | d_{Ru} = 5.9241 nm |
| 41 | d_{Si} = 9.6964 nm | d_{Ru} = 5.7233 nm |
| 42 | d_{Si} = 9.6632 nm | d_{Ru} = 5.5086 nm |
| 43 | d_{Si} = 9.6117 nm | d_{Ru} = 5.2655 nm |
| 44 | d_{Si} = 9.5779 nm | d_{Ru} = 4.8707 nm |
| 45 | d_{Si} = 9.7328 nm | d_{Ru} = 4.2078 nm |
| 46 | d_{Si} = 10.0269 nm | d_{Ru} = 3.6662 nm |
| 47 | d_{Si} = 10.2061 nm | d_{Ru} = 3.4160 nm |
| 48 | d_{Si} = 10.2024 nm | d_{Ru} = 3.4533 nm |
| 49 | d_{Si} = 10.0420 nm | d_{Ru} = 3.9104 nm |
| 50 | d_{Si} = 9.8148 nm | d_{Ru} = 4.2305 nm |

TABLE 2
(RuSi; 60° angle of incidence; rₛ = 0.7; rₚ maximal
The silicon layer of layer 1 is located directly on the
substrate. The ruthenium layer of layer 50 forms the
incidence surface for the EUV used radiation.)

| | | |
|---|---|---|
| 1 | d_{Si} = 0.0000 nm | d_{Ru} = 6.8950 nm |
| 2 | d_{Si} = 8.7943 nm | d_{Ru} = 0.0000 nm |
| 3 | d_{Si} = 0.0000 nm | d_{Ru} = 0.0000 nm |
| 4 | d_{Si} = 14.0000 nm | d_{Ru} = 11.1499 nm |
| 5 | d_{Si} = 0.0000 nm | d_{Ru} = 14.0000 nm |
| 6 | d_{Si} = 14.0000 nm | d_{Ru} = 0.0000 nm |
| 7 | d_{Si} = 14.0000 nm | d_{Ru} = 14.0000 nm |
| 8 | d_{Si} = 7.7458 nm | d_{Ru} = 12.7017 nm |
| 9 | d_{Si} = 5.4784 nm | d_{Ru} = 9.9048 nm |
| 10 | d_{Si} = 11.8243 nm | d_{Ru} = 9.2929 nm |
| 11 | d_{Si} = 5.8627 nm | d_{Ru} = 10.5026 nm |
| 12 | d_{Si} = 10.1953 nm | d_{Ru} = 10.0703 nm |
| 13 | d_{Si} = 5.3878 nm | d_{Ru} = 10.7100 nm |
| 14 | d_{Si} = 11.6359 nm | d_{Ru} = 9.1818 nm |
| 15 | d_{Si} = 5.2900 nm | d_{Ru} = 0.0247 nm |
| 16 | d_{Si} = 0.0904 nm | d_{Ru} = 0.0927 nm |
| 17 | d_{Si} = 0.4027 nm | d_{Ru} = 11.7905 nm |
| 18 | d_{Si} = 8.7352 nm | d_{Ru} = 0.0000 nm |
| 19 | d_{Si} = 0.0104 nm | d_{Ru} = 10.9638 nm |
| 20 | d_{Si} = 5.8251 nm | d_{Ru} = 10.8651 nm |
| 21 | d_{Si} = 10.1334 nm | d_{Ru} = 10.2689 nm |
| 22 | d_{Si} = 4.7854 nm | d_{Ru} = 10.9044 nm |
| 23 | d_{Si} = 11.1279 nm | d_{Ru} = 0.0000 nm |
| 24 | d_{Si} = 13.9900 nm | d_{Ru} = 0.0000 nm |
| 25 | d_{Si} = 13.4481 nm | d_{Ru} = 0.0000 nm |
| 26 | d_{Si} = 13.9864 nm | d_{Ru} = 6.4612 nm |
| 27 | d_{Si} = 10.3630 nm | d_{Ru} = 0.7886 nm |
| 28 | d_{Si} = 13.2990 nm | d_{Ru} = 0.0000 nm |
| 29 | d_{Si} = 13.0715 nm | d_{Ru} = 0.0000 nm |
| 30 | d_{Si} = 13.1670 nm | d_{Ru} = 7.2923 nm |
| 31 | d_{Si} = 14.0000 nm | d_{Ru} = 0.0350 nm |
| 32 | d_{Si} = 0.0455 nm | d_{Ru} = 0.0508 nm |
| 33 | d_{Si} = 0.0000 nm | d_{Ru} = 0.0052 nm |
| 34 | d_{Si} = 9.0992 nm | d_{Ru} = 5.3858 nm |
| 35 | d_{Si} = 9.1359 nm | d_{Ru} = 9.1692 nm |
| 36 | d_{Si} = 9.0522 nm | d_{Ru} = 6.6343 nm |
| 37 | d_{Si} = 9.4914 nm | d_{Ru} = 6.8441 nm |
| 38 | d_{Si} = 9.7028 nm | d_{Ru} = 5.9849 nm |
| 39 | d_{Si} = 10.0724 nm | d_{Ru} = 5.4631 nm |
| 40 | d_{Si} = 10.2388 nm | d_{Ru} = 5.2962 nm |
| 41 | d_{Si} = 10.3055 nm | d_{Ru} = 5.2011 nm |
| 42 | d_{Si} = 10.3321 nm | d_{Ru} = 5.1586 nm |
| 43 | d_{Si} = 10.3539 nm | d_{Ru} = 5.1052 nm |
| 44 | d_{Si} = 10.3842 nm | d_{Ru} = 5.0677 nm |
| 45 | d_{Si} = 10.4049 nm | d_{Ru} = 5.0421 nm |
| 46 | d_{Si} = 10.4114 nm | d_{Ru} = 5.0427 nm |
| 47 | d_{Si} = 10.3725 nm | d_{Ru} = 5.1956 nm |
| 48 | d_{Si} = 10.1710 nm | d_{Ru} = 5.6085 nm |
| 49 | d_{Si} = 9.9845 nm | d_{Ru} = 5.8591 nm |
| 50 | d_{Si} = 10.0288 nm | d_{Ru} = 5.1012 nm |

TABLE 3
(MoSi; 25° angle of incidence; rₛ = 0.7; rₚ minimal
The silicon layer of layer 1 is located directly on the
substrate. The molybdenum layer of layer 50 forms the
incidence surface for the EUV used radiation.)

| | | |
|---|---|---|
| 1 | d_{Si} = 7.7236 nm | d_{Mo} = 4.1247 nm |
| 2 | d_{Si} = 3.7727 nm | d_{Mo} = 3.9637 nm |
| 3 | d_{Si} = 3.8103 nm | d_{Mo} = 3.9256 nm |
| 4 | d_{Si} = 3.8385 nm | d_{Mo} = 3.8985 nm |
| 5 | d_{Si} = 3.8613 nm | d_{Mo} = 3.8772 nm |
| 6 | d_{Si} = 3.8799 nm | d_{Mo} = 3.8583 nm |
| 7 | d_{Si} = 3.8964 nm | d_{Mo} = 3.8414 nm |
| 8 | d_{Si} = 3.9109 nm | d_{Mo} = 3.8256 nm |
| 9 | d_{Si} = 3.9239 nm | d_{Mo} = 3.8104 nm |
| 10 | d_{Si} = 3.9358 nm | d_{Mo} = 3.7956 nm |
| 11 | d_{Si} = 3.9469 nm | d_{Mo} = 3.7812 nm |
| 12 | d_{Si} = 3.9572 nm | d_{Mo} = 3.7669 nm |
| 13 | d_{Si} = 3.9667 nm | d_{Mo} = 3.7531 nm |
| 14 | d_{Si} = 3.9749 nm | d_{Mo} = 3.7412 nm |
| 15 | d_{Si} = 3.9796 nm | d_{Mo} = 3.7352 nm |
| 16 | d_{Si} = 3.9756 nm | d_{Mo} = 3.7421 nm |
| 17 | d_{Si} = 3.9559 nm | d_{Mo} = 3.7678 nm |
| 18 | d_{Si} = 3.9223 nm | d_{Mo} = 3.7969 nm |
| 19 | d_{Si} = 3.8955 nm | d_{Mo} = 3.8291 nm |
| 20 | d_{Si} = 3.8322 nm | d_{Mo} = 3.9131 nm |
| 21 | d_{Si} = 3.7738 nm | d_{Mo} = 3.9415 nm |
| 22 | d_{Si} = 3.7078 nm | d_{Mo} = 4.0771 nm |
| 23 | d_{Si} = 3.5857 nm | d_{Mo} = 4.0850 nm |
| 24 | d_{Si} = 3.7453 nm | d_{Mo} = 3.7996 nm |
| 25 | d_{Si} = 3.8214 nm | d_{Mo} = 4.0151 nm |
| 26 | d_{Si} = 3.6689 nm | d_{Mo} = 3.8402 nm |
| 27 | d_{Si} = 3.8079 nm | d_{Mo} = 4.0464 nm |
| 28 | d_{Si} = 3.4973 nm | d_{Mo} = 4.2351 nm |
| 29 | d_{Si} = 3.4044 nm | d_{Mo} = 4.3481 nm |
| 30 | d_{Si} = 3.1417 nm | d_{Mo} = 4.7698 nm |
| 31 | d_{Si} = 3.2269 nm | d_{Mo} = 4.2264 nm |
| 32 | d_{Si} = 3.0257 nm | d_{Mo} = 5.1157 nm |
| 33 | d_{Si} = 2.9847 nm | d_{Mo} = 4.3411 nm |
| 34 | d_{Si} = 3.2408 nm | d_{Mo} = 4.7565 nm |
| 35 | d_{Si} = 2.9068 nm | d_{Mo} = 4.6206 nm |
| 36 | d_{Si} = 3.2913 nm | d_{Mo} = 4.2183 nm |
| 37 | d_{Si} = 3.2794 nm | d_{Mo} = 4.9177 nm |
| 38 | d_{Si} = 2.8443 nm | d_{Mo} = 4.1465 nm |
| 39 | d_{Si} = 3.9148 nm | d_{Mo} = 4.0578 nm |
| 40 | d_{Si} = 3.1493 nm | d_{Mo} = 4.7295 nm |
| 41 | d_{Si} = 2.9040 nm | d_{Mo} = 4.8262 nm |
| 42 | d_{Si} = 3.2651 nm | d_{Mo} = 4.1901 nm |
| 43 | d_{Si} = 3.4998 nm | d_{Mo} = 4.1952 nm |
| 44 | d_{Si} = 3.6395 nm | d_{Mo} = 3.8621 nm |
| 45 | d_{Si} = 3.9863 nm | d_{Mo} = 3.5529 nm |
| 46 | d_{Si} = 4.2105 nm | d_{Mo} = 3.3495 nm |
| 47 | d_{Si} = 4.4049 nm | d_{Mo} = 3.1676 nm |
| 48 | d_{Si} = 4.5380 nm | d_{Mo} = 3.0782 nm |
| 49 | d_{Si} = 4.5974 nm | d_{Mo} = 3.0348 nm |
| 50 | d_{Si} = 4.6360 nm | d_{Mo} = 2.7202 nm |

TABLE 4
(MoSi; 25° angle of incidence; rₛ = 0.7; rₚ maximal
The silicon layer of layer 1 is located directly on the
substrate. The molybdenum layer of layer 50 forms the
incidence surface for the EUV used radiation.)

| | | |
|---|---|---|
| 1 | d_{Si} = 7.7236 nm | d_{Mo} = 4.1079 nm |
| 2 | d_{Si} = 3.7634 nm | d_{Mo} = 4.0723 nm |
| 3 | d_{Si} = 3.7981 nm | d_{Mo} = 4.0300 nm |
| 4 | d_{Si} = 3.8289 nm | d_{Mo} = 3.9941 nm |
| 5 | d_{Si} = 3.8583 nm | d_{Mo} = 3.9596 nm |
| 6 | d_{Si} = 3.8868 nm | d_{Mo} = 3.9262 nm |
| 7 | d_{Si} = 3.9146 nm | d_{Mo} = 3.8937 nm |
| 8 | d_{Si} = 3.9418 nm | d_{Mo} = 3.8612 nm |
| 9 | d_{Si} = 3.9695 nm | d_{Mo} = 3.8301 nm |
| 10 | d_{Si} = 3.9949 nm | d_{Mo} = 3.8004 nm |
| 11 | d_{Si} = 4.0206 nm | d_{Mo} = 3.7699 nm |
| 12 | d_{Si} = 4.0475 nm | d_{Mo} = 3.7368 nm |
| 13 | d_{Si} = 4.0796 nm | d_{Mo} = 3.6934 nm |
| 14 | d_{Si} = 4.1263 nm | d_{Mo} = 3.6282 nm |
| 15 | d_{Si} = 4.1977 nm | d_{Mo} = 3.5317 nm |
| 16 | d_{Si} = 4.2988 nm | d_{Mo} = 3.4037 nm |
| 17 | d_{Si} = 4.4256 nm | d_{Mo} = 3.2523 nm |
| 18 | d_{Si} = 4.5682 nm | d_{Mo} = 3.0900 nm |
| 19 | d_{Si} = 4.7158 nm | d_{Mo} = 2.9279 nm |
| 20 | d_{Si} = 4.8592 nm | d_{Mo} = 2.7741 nm |
| 21 | d_{Si} = 4.9929 nm | d_{Mo} = 2.6332 nm |
| 22 | d_{Si} = 5.1140 nm | d_{Mo} = 2.5072 nm |
| 23 | d_{Si} = 5.2216 nm | d_{Mo} = 2.3959 nm |
| 24 | d_{Si} = 5.3162 nm | d_{Mo} = 2.2988 nm |
| 25 | d_{Si} = 5.3987 nm | d_{Mo} = 2.2143 nm |
| 26 | d_{Si} = 5.4705 nm | d_{Mo} = 2.1410 nm |
| 27 | d_{Si} = 5.5327 nm | d_{Mo} = 2.0777 nm |
| 28 | d_{Si} = 5.5866 nm | d_{Mo} = 2.0230 nm |
| 29 | d_{Si} = 5.6333 nm | d_{Mo} = 1.9757 nm |
| 30 | d_{Si} = 5.6738 nm | d_{Mo} = 1.9348 nm |
| 31 | d_{Si} = 5.7090 nm | d_{Mo} = 1.8994 nm |
| 32 | d_{Si} = 5.7396 nm | d_{Mo} = 1.8687 nm |
| 33 | d_{Si} = 5.7662 nm | d_{Mo} = 1.8423 nm |
| 34 | d_{Si} = 5.7893 nm | d_{Mo} = 1.8196 nm |
| 35 | d_{Si} = 5.8094 nm | d_{Mo} = 1.8002 nm |
| 36 | d_{Si} = 5.8266 nm | d_{Mo} = 1.7837 nm |
| 37 | d_{Si} = 5.8414 nm | d_{Mo} = 1.7701 nm |
| 38 | d_{Si} = 5.8540 nm | d_{Mo} = 1.7589 nm |
| 39 | d_{Si} = 5.8646 nm | d_{Mo} = 1.7502 nm |
| 40 | d_{Si} = 5.8737 nm | d_{Mo} = 1.7438 nm |
| 41 | d_{Si} = 5.8815 nm | d_{Mo} = 1.7397 nm |
| 42 | d_{Si} = 5.8885 nm | d_{Mo} = 1.7380 nm |
| 43 | d_{Si} = 5.8946 nm | d_{Mo} = 1.7395 nm |
| 44 | d_{Si} = 5.8983 nm | d_{Mo} = 1.7449 nm |
| 45 | d_{Si} = 5.9017 nm | d_{Mo} = 1.7537 nm |
| 46 | d_{Si} = 5.9027 nm | d_{Mo} = 1.7675 nm |
| 47 | d_{Si} = 5.8995 nm | d_{Mo} = 1.7883 nm |
| 48 | d_{Si} = 5.8868 nm | d_{Mo} = 1.8176 nm |
| 49 | d_{Si} = 5.8528 nm | d_{Mo} = 1.9389 nm |
| 50 | d_{Si} = 5.7606 nm | d_{Mo} = 2.5331 nm |

Exchanging at least one reflective component located in the optical beam path for a component that corresponds with respect to its surface geometry but differs with respect to the reflection layer system present, for the purposes of changing the operating mode between “polarized” and “unpolarized”, can generally be realized for different components of the optical system or of the illumination device.

FIG. 8 initially shows a schematic and much simplified representation of a possible basic structure of an illumination device of a microlithographic projection exposure apparatus designed for operation in the EUV wavelength range. In this case, the EUV radiation produced by an EUV radiation source 802 (e.g. a plasma source) reaches a field facet mirror 810 with a multiplicity of independently adjustable field facets (e.g. for setting different illumination settings) via an intermediate focus 801 following the reflection at a collector mirror 803. From the field facet mirror 810, the EUV radiation is incident on a pupil facet mirror 820 and, from the latter, on a reticle 830 which is situated in the object plane of the projection lens (not depicted in FIG. 8) disposed downstream in the optical beam path.

The disclosure is not restricted to the structure of the illumination device as illustrated in FIG. 8. Thus, one or more additional optical elements, for example in the form of one or more deflection mirrors, can also be arranged in the beam path in further embodiments.

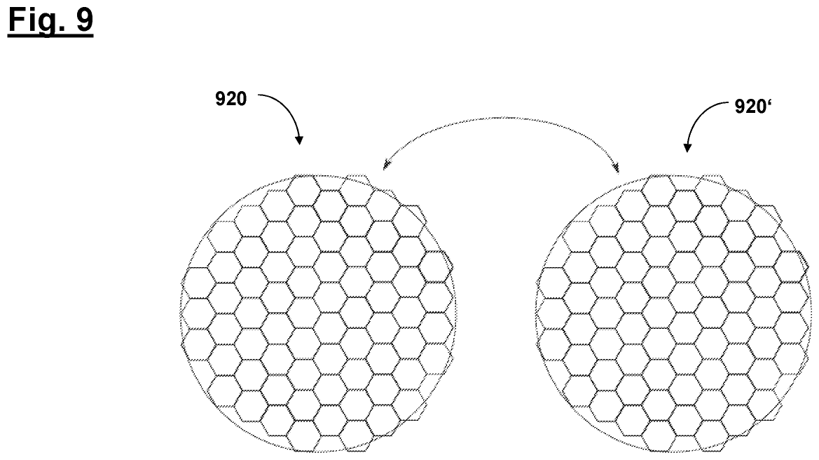

Possible implementations of the “component exchange” according to the disclosure are explained below with reference to the merely schematic illustrations of FIGS. 9-12.

With reference to FIG. 9, initially, the pupil facet mirror (denoted by “920” in FIG. 9) can be exchanged overall for another pupil facet mirror 920′ (which according to the concept according to the disclosure differs from the pupil facet mirror 920 not in terms of its surface geometry but in terms of its spectral reflection profiles or reflection layer systems) for the purposes of implementing the component exchange according to the disclosure for the purpose of changing the operating mode between “polarized” and “unpolarized”. This implementation can be advantageous inasmuch as only a single component has to be exchanged.

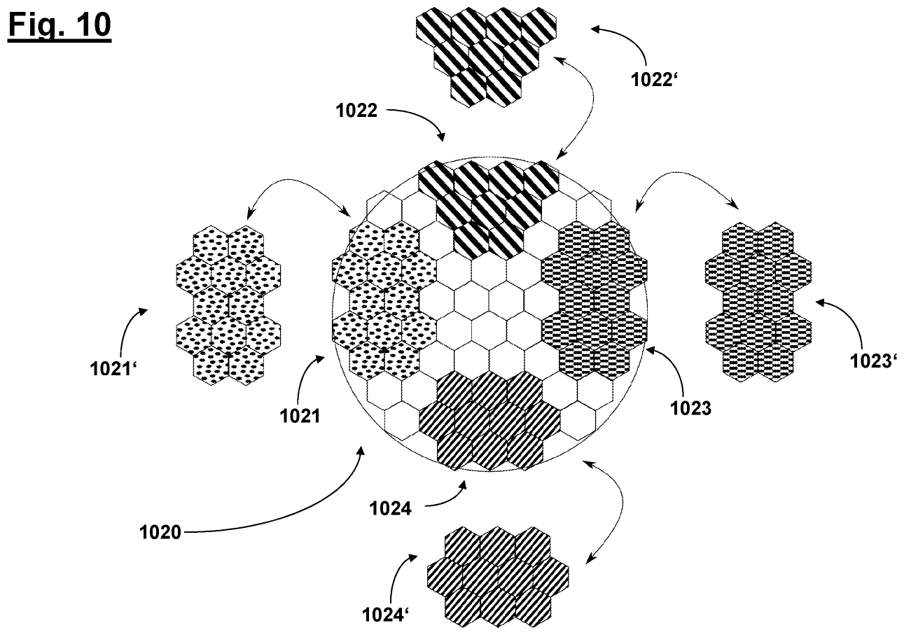

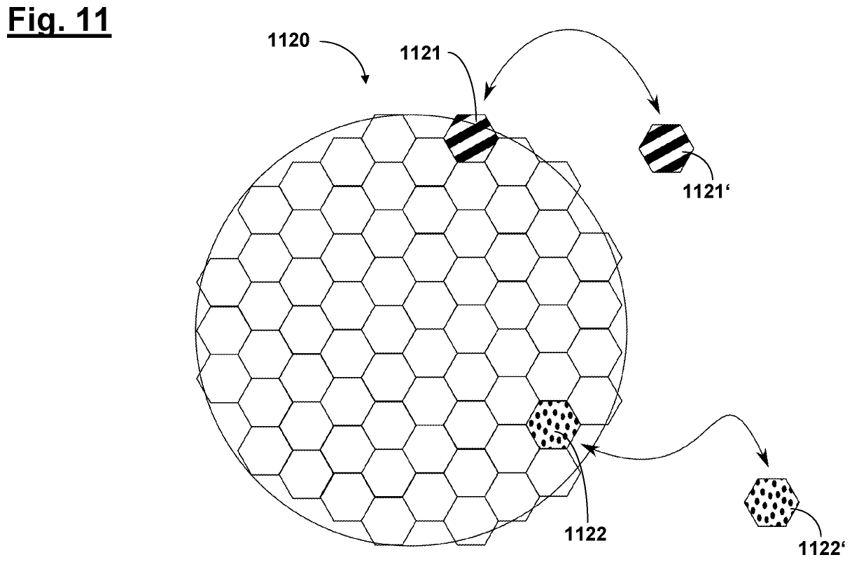

In a further embodiment, elucidated in FIG. 10, it is also possible to exchange individual segments (denoted by “1021” to “1024” in FIG. 10) of a pupil facet mirror 1020 for other segments (denoted “1021′” to “1024′” in FIG. 10), with the respective segments in turn comprising a plurality of pupil facets. This embodiment is advantageous inasmuch as the number of elements to be realized as exchangeable is comparatively small. As indicated in FIG. 11, a single pupil facet (e.g. “1121” or “1122”) of a pupil facet mirror 1120 can also be exchanged for another pupil facet 1121′ or 1122′ (which in conformity with the concept according to the disclosure is designed with the same surface geometry but different spectral reflection profiles or reflection layer systems) in a further embodiment.

To the extent that reference is made to a pupil facet mirror in the embodiments described above, there can be an analogous realization for the field facet mirror as well.

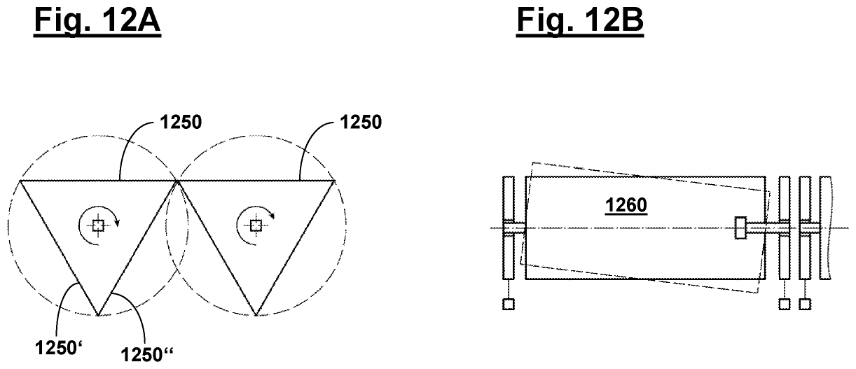

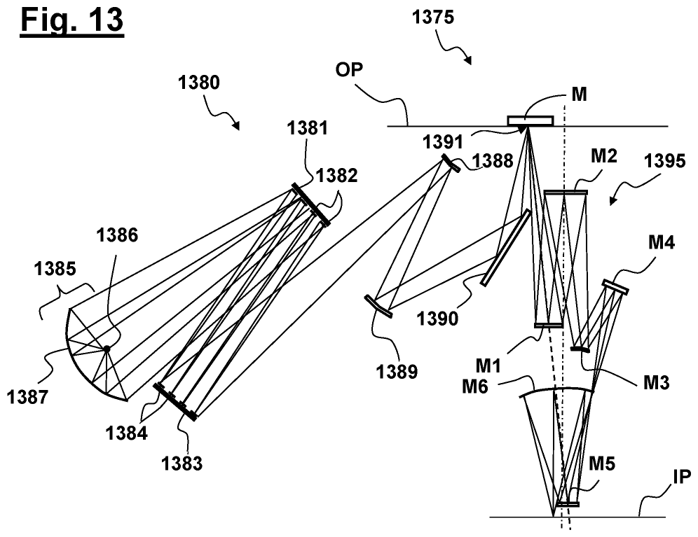

FIGS. 12A-12B show, purely in a schematic representation, a further implementation option for the component interchange according to the disclosure. In this case, up to three field facets 1250, 1250′, 1250″ can be arranged on an exchange apparatus 1260 designed as a roller, in an arrangement known per se from DE 10 2018 207 410 A1, with rotating the roller allowing a “switch” between the field facets 1250, 1250′, 1250″. By tilting the axis of rotation, the respective selected field facet 1250, 1250′ or 1250″ can be tilted so that a desired pupil facet of the pupil facet mirror is illuminated. In this case, according to the disclosure, the three field facets 1250, 1250′, 1250″ situated on a common roller are provided with different reflection layer systems.

In a further variant, the reflection layer systems can be attached to the collector mirror 803, reference having made to FIG. 8 again. Embodiments of a collector mirror for simplifying the highly accurate interchange thereof are known from DE 10 2013 200 368 A1.

FIG. 13 shows a schematic illustration of an exemplary projection exposure apparatus which is designed for operation in the EUV and in which the present disclosure can be realized. According to FIG. 13, an illumination device 1380 in a projection exposure apparatus 1375 designed for EUV comprises a field facet mirror 1381 (with facets 1382) and a pupil facet mirror 1383 (with facets 1384). The light from a light source unit 1385 comprising a plasma light source 1386 and a collector mirror 1387 is directed at the field facet mirror 1381. A first telescope mirror 1388 and a second telescope mirror 1389 are arranged in the light path downstream of the pupil facet mirror 1383. A deflection mirror 1390 is arranged downstream in the light path, the deflection mirror steering the radiation that is incident thereon to an object field 1391 in the object plane OP of a projection lens 1395 comprising six mirrors M1-M6. A reflective structure-bearing mask M, which is imaged into an image plane IP with the aid of the projection lens 1395 (comprising six mirrors M1-M6), is arranged at the location of the object field 1391.

Even though the disclosure has been described on the basis of specific embodiments, numerous variations and alternative embodiments will be apparent to a person skilled in the art, for example through combination and/or exchange of features of individual embodiments. Accordingly, it will be apparent to a person skilled in the art that such variations and alternative embodiments are also encompassed by the present disclosure, and the scope of the disclosure is restricted only within the scope of the appended patent claims and the equivalents thereof.

What is claimed is:

1. An EUV illumination device having an optical beam path, the EUV illumination device comprising:
a first reflective component;
a second reflective component; and
an exchange apparatus configured to exchange the first reflective component and the second reflective component in the optical beam path for one another,
wherein a polarization degree, defined as a ratio between the reflectivities for s-polarized and p-polarized radiation, of the first reflective component is at least 1.5 greater than for the second reflective component.

2. The EUV illumination device of claim 1, wherein each of the first and second reflective components comprises a mirror facet of a facet mirror.

3. The EUV illumination device of claim 1, wherein each of the first and second reflective components comprises a mirror facet of a pupil facet mirror.

4. The EUV illumination device of claim 1, wherein each of the first and second reflective components comprises a mirror facet of a field facet mirror.

5. The EUV illumination device of claim 1, wherein each of the first and second reflective components comprise a facet mirror.

6. The EUV illumination device of claim 1, wherein each of the first and second reflective components comprises a pupil facet mirror comprising a plurality of pupil facets.

7. The EUV illumination device of claim 1, wherein each of the first and second reflective components comprises a field facet mirror comprising a plurality of field facets.

8. The EUV illumination device of claim 1, wherein each of the first and second reflective components comprises a micromirror of a specular reflector.

9. The EUV illumination device of claim 1, wherein each of the first and the second reflective components comprises a collector mirror.

10. The EUV illumination device of claim 1, wherein a wavelength λ₀ is a mean wavelength in a wavelength interval [(λ₀−Δλ₀/2), (λ₀+Δλ₀/2)] of width Δλ₀ such that the first reflection layer system satisfies the following conditions:
$$( {λ}_{0} - Δ {λ}_{0} / 2 ) \geq {λ}_{1 s l} , ( {λ}_{0} + Δ {λ}_{0} / 2 ) \leq {λ}_{1 s r}$$
$$and$$
$$( {λ}_{0} - Δ {λ}_{0} / 2 ) \leq {λ}_{1 pl} or ( {λ}_{0} + Δ {λ}_{0} / 2 ) \geq {λ}_{1 pr} ,$$
where, in reflection profiles (r₁ₛ(λ), r₁ₚ(λ)) of the first reflection layer system, λ₁ₛₗ and λ₁ₚₗ, denote the shortest wavelength and λ₁ₛᵣ and λ₁ₚᵣ denote a longest wavelength for which in each case s-polarized and p-polarized radiation, respectively, is reflected with a reflectivity of at least 50% of the maximum reflectivity.

11. The EUV illumination device of claim 1, wherein a wavelength λ₀ is a mean wavelength in a wavelength interval [(λ₀−Δλ₀/2), (λ₀+Δλ₀/2)] of width Δλ₀ such that the second reflection layer system satisfies the following conditions:
$$( {λ}_{0} - Δ {λ}_{0} / 2 ) \geq {λ}_{2 s l} , ( {λ}_{0} + Δ {λ}_{0} / 2 ) \leq {λ}_{2 s r}$$
$$and$$
$$( {λ}_{0} - Δ {λ}_{0} / 2 ) \geq {λ}_{2 p l} , ( {λ}_{0} + Δ {λ}_{0} / 2 ) \leq {λ}_{2 p r}$$
where, in reflection profiles (r₂ₛ(λ), r₂ₚ(λ)) of the second reflection layer system, λ₂ₛₗ and λ₂ₚₗ denote the shortest wavelength and λ₂ₛᵣ and λ₂ₚᵣ denote the longest wavelength for which in each case s-polarized and p-polarized radiation, respectively, is reflected with a reflectivity of at least 50% of the maximum reflectivity.

12. The EUV illumination device of claim 1, wherein a wavelength λ₀ is a mean wavelength in a wavelength interval [(λ₀−Δλ₀/2), (λ₀+Δλ₀/2)] of width Δλ₀ such that the first reflection layer system satisfies the following conditions:
$$( {λ}_{0} - Δ {λ}_{0} / 2 ) \geq {λ}_{1 s l} , ( {λ}_{0} + Δ {λ}_{0} / 2 ) \leq {λ}_{1 s r}$$
$$and$$
$$( {λ}_{0} - Δ {λ}_{0} / 2 ) \leq {λ}_{1 pl} or ( {λ}_{0} + Δ {λ}_{0} / 2 ) \geq {λ}_{1 pr} ,$$
and the second reflection layer system satisfies the following conditions:
$$( {λ}_{0} - Δ {λ}_{0} / 2 ) \geq {λ}_{2 s l} , ( {λ}_{0} + Δ {λ}_{0} / 2 ) \leq {λ}_{2 s r}$$
$$and$$
$$( {λ}_{0} - Δ {λ}_{0} / 2 ) \geq {λ}_{2 p l} , ( {λ}_{0} + Δ {λ}_{0} / 2 ) \leq {λ}_{2 p r}$$
wherein, in reflection profiles (r₁ₛ(λ), r₁ₚ(λ)) of the first reflection layer system and (r₂ₛ(λ), r₂ₚ(λ)) of the second reflection layer system, λ₁ₛₗ, λ₁ₚₗ, λ₂ₛₗ and λ₂ₚₗ denote respective shortest wavelengths and λ₁ₛᵣ, λ₁ₚᵣ, λ₂ₛᵣ and λ₂ₚᵣ denote respective longest wavelengths for which in each case s-polarized and p-polarized radiation, respectively, is reflected with a reflectivity of at least 50% of the maximum reflectivity.

13. The EUV illumination device of claim 1, wherein:
for s-polarized radiation in a wavelength interval [( [symbol] − [symbol] );( [symbol] + [symbol] )], the EUV illumination device has a transmissivity of at least 50% of a maximum transmissivity of the EUV illumination device; and
Δλ₀ is between [symbol] and [symbol] .

14. The EUV illumination device of claim 13, wherein a wavelength λ₀ is a mean wavelength in a wavelength interval [(λ₀−Δλ₀/2), (λ₀+Δλ₀/2)] of width Δλ₀ such that the first reflection layer system satisfies the following conditions:
$$( {λ}_{0} - Δ {λ}_{0} / 2 ) \geq {λ}_{1 s l} , ( {λ}_{0} + Δ {λ}_{0} / 2 ) \leq {λ}_{1 s r}$$
$$and$$
$$( {λ}_{0} - Δ {λ}_{0} / 2 ) \leq {λ}_{1 pl} or ( {λ}_{0} + Δ {λ}_{0} / 2 ) \geq {λ}_{1 pr} ,$$
where, in reflection profiles (r₁ₛ(λ), r₁ₚ(λ)) of the first reflection layer system, λ₁ₛₗ and λ₁ₚₗ denote the shortest wavelength and λ₁ₛᵣ and λ₁ₚᵣ denote a longest wavelength for which in each case s-polarized and p-polarized radiation, respectively, is reflected with a reflectivity of at least 50% of the maximum reflectivity.

15. The EUV illumination device of claim 13, wherein a wavelength λ₀ is a mean wavelength in a wavelength interval [(λ₀−Δλ₀/2), (λ₀+Δλ₀/2)] of width Δλ₀ such that the second reflection layer system satisfies the following conditions:
$$( {λ}_{0} - Δ {λ}_{0} / 2 ) \geq {λ}_{2 s l} , ( {λ}_{0} + Δ {λ}_{0} / 2 ) \leq {λ}_{2 s r}$$
$$and$$
$$( {λ}_{0} - Δ {λ}_{0} / 2 ) \geq {λ}_{2 p l} , ( {λ}_{0} + Δ {λ}_{0} / 2 ) \leq {λ}_{2 p r}$$
where, in reflection profiles (r₂ₛ(λ), r₂ₚ(λ)) of the second reflection layer system, λ₂ₛₗ and λ₂ₚₗ denote the shortest wavelength and λ₂ₛᵣ and λ₂ₚᵣ denote the longest wavelength for which in each case s-polarized and p-polarized radiation, respectively, is reflected with a reflectivity of at least 50% of the maximum reflectivity.

16. The EUV illumination device of claim 13, wherein a wavelength λ₀ is a mean wavelength in a wavelength interval [(λ₀−Δλ₀/2), (λ₀+Δλ₀/2)] of width Δλ₀ such that the first reflection layer system satisfies the following conditions:
$$( {λ}_{0} - Δ {λ}_{0} / 2 ) \geq {λ}_{1 s l} , ( {λ}_{0} + Δ {λ}_{0} / 2 ) \leq {λ}_{1 s r}$$
$$and$$
$$( {λ}_{0} - Δ {λ}_{0} / 2 ) \leq {λ}_{1 pl} or ( {λ}_{0} + Δ {λ}_{0} / 2 ) \geq {λ}_{1 pr} ,$$
and the second reflection layer system satisfies the following conditions:
$$( {λ}_{0} - Δ {λ}_{0} / 2 ) \geq {λ}_{2 s l} , ( {λ}_{0} + Δ {λ}_{0} / 2 ) \leq {λ}_{2 s r}$$
$$and$$
$$( {λ}_{0} - Δ {λ}_{0} / 2 ) \geq {λ}_{2 p l} , ( {λ}_{0} + Δ {λ}_{0} / 2 ) \leq {λ}_{2 p r}$$
wherein, in reflection profiles (r₁ₛ(λ), r₁ₚ(λ)) of the first reflection layer system and (r₂ₛ(λ), r₂p((λ)) of the second reflection layer system, λ₁ₛₗ, λ₁ₚₗ, λ₂ₛₗ and λ₂ₚₗ denote respective shortest wavelengths and λ₁ₛᵣ, λ₁ₚᵣ, λ₂ₛᵣ and λ₂ₚᵣ denote respective longest wavelengths for which in each case s-polarized and p-polarized radiation, respectively, is reflected with a reflectivity of at least 50% of the maximum reflectivity.

17. The EUV illumination device of claim 13, wherein each of the first and second reflective components comprises a mirror facet of a facet mirror.

18. The EUV illumination device of claim 13, wherein each of the first and second reflective components comprise a facet mirror.

19. An apparatus, comprising:
an EUV illumination device according to claim 1; and
a projection lens,
wherein the apparatus is a microlithographic projection exposure apparatus.

20. A method of operating an EUV microlithographic projection exposure apparatus comprising an illumination device and a projection lens, the method comprising:
using the illumination device to illuminate an object plane of the projection lens;
using the projection lens to image the object plane into an image plane of the projection lens; and
switching between a polarized operating mode and an unpolarized operating mode by exchanging a first reflective component comprising a first reflection layer system located in an optical beam path of the illumination device for a second reflective component comprising a second reflection layer system,
wherein a polarization degree, defined as a ratio between the reflectivities for s-polarized and p-polarized radiation, of the first reflective component is at least 1.5 greater than for the second reflective component.
